(19) United States
(12) Patent Application Publication
(10) Pub. No.: US 2011/0057244 A1
(43) Pub. Date: Mar. 10, 2011

(54) SEMICONDUCTOR DEVICE AND METHOD OF MANUFACTURING THE SAME

(75) Inventor: Kenji GOMIKAWA, Yokohama-shi (JP)

(73) Assignee: KABUSHIKI KAISHA TOSHIBA, Tokyo (JP)

(21) Appl. No.: 12/728,432

(22) Filed: Mar. 22, 2010

(30) Foreign Application Priority Data
Sep. 10, 2009 (JP) 2009-208919

(51) Int. Cl. H01L 27/11; H01L 21/8239

(52) U.S. Cl. 257/316; 438/258; 257/E21.645; 257/E27.098

(57) ABSTRACT

A method of manufacturing a semiconductor device, comprising: forming, on a semiconductor substrate a gate insulating film for a high-voltage transistor of a peripheral circuit; forming on the gate insulating film a gate electrode for the high-voltage transistor; removing the gate insulating film positioned on the semiconductor substrate on both side portions of the gate electrode; forming an impurity diffusion region in a surface of the semiconductor substrate; depositing a first silicon oxide film to extend over surfaces of the gate electrode and the impurity diffusion region; etching the first silicon oxide film to form a spacer such that the spacer is formed on a side wall portion of the gate electrode and also extends over the surface of the semiconductor substrate; and forming a silicon nitride film on a surface of the spacer.

### CROSS REFERENCE TO RELATED APPLICATIONS

This application is based upon and claims the benefit of priority from prior Japanese Patent Application No. 2009-208919, filed on Sep. 10, 2009, the entire contents of which are incorporated herein by reference.

### BACKGROUND OF THE INVENTION

1. Field of the Invention

The present invention relates to a semiconductor device, in particular, a high-voltage transistor used in a peripheral circuit region of a nonvolatile semiconductor memory device, and a method of manufacturing the same.

2. Description of the Related Art

NAND flash memory is known as a nonvolatile semiconductor memory device that is electrically rewritable and capable of a high degree of integration (EEPROM). In NAND flash memory, a plurality of memory cells are connected in series such that adjacent memory cells share source/drain regions, thereby configuring a NAND cell unit. The two ends of the NAND cell unit are respectively connected to a bit line and a source line via select gate transistors. Such a NAND cell unit configuration allows a smaller unit cell area and larger storage capacity than a NOR configuration.

In NAND flash memory, a spacer is provided on a side wall of the select gate transistor, the spacer being configured by an insulating film. In addition, a bit line contact is provided adjacent to the select gate transistor. A silicon nitride film which acts as a barrier film during formation of a contact hole of the bit line contact or liner film is provided on the spacer.

Moreover, since NAND flash memory requires that a high voltage be applied to a memory cell transistor during write and erase of data, there is a high-voltage transistor formed in a peripheral circuit region. A gate insulating film of this high-voltage transistor has a film thickness formed greater than that of a gate insulating film of the memory cell transistor or select gate transistor.

When executing the above-mentioned formation of the spacer on the transistor side wall and formation of the silicon nitride film acting as the barrier film, etching during formation of a gate electrode sometimes causes the gate oxide film to be removed, whereby the silicon nitride film is formed directly on the silicon substrate surface. If the silicon nitride film is formed directly on the silicon substrate surface of the high-voltage transistor in the peripheral circuit region, this may be a source of traps in the gate oxide film, for example, and cause a deterioration in reliability of the high-voltage transistor. A configuration for avoiding this is known, in which a separate silicon oxide film is introduced between the silicon nitride film and the silicon substrate to prevent direct contact between the silicon nitride film and the silicon substrate (refer, for example, to JP 2008-98567 A and JP 2006-41023 A).

However, when the high-voltage transistor is formed using these publicly-known methods, a difference in height occurs in two places in a portion of the silicon substrate near the gate electrode above the source/drain region (refer, for example, to JP 2006-324503 A). These differences in height are caused by two executions of etching, namely, etching during formation of the gate electrode and etching when removing unnecessary side wall spacer insulating film extending over the substrate surface. Since, in general, the method of etching employed to remove the gate insulating film of large film thickness during formation of the gate electrode is RIE (Reactive Ion Etching), there is a risk that over-etching occurs. This leads to the problem of deterioration in fundamental characteristics and reliability of the high-voltage transistor.

### SUMMARY OF THE INVENTION

In accordance with a first aspect of the present invention, a method of manufacturing a semiconductor device comprises: forming, on a semiconductor substrate, a first gate insulating film for memory cell transistors, and a second gate insulating film for a high-voltage transistor of a peripheral circuit; forming on the first gate insulating film a plurality of first gate electrodes for the memory cell transistors, and on the second gate insulating film a second gate electrode for the high-voltage transistor; removing the second gate insulating film positioned on the semiconductor substrate on both side portions of the second gate electrode; forming an impurity diffusion region in a surface of the semiconductor substrate positioned on both side portions of the first gate electrodes and the second gate electrode; depositing a first silicon oxide film to fill between the plurality of first gate electrodes and also to extend over surfaces of the second gate electrode and the impurity diffusion region; etching the first silicon oxide film to form a spacer such that the spacer is formed on a side wall portion of the second gate electrode and also extends over the surface of the semiconductor substrate where the impurity diffusion region is provided; and forming a silicon nitride film on a surface of the spacer.

In accordance with a second aspect of the present invention, a method of manufacturing a semiconductor device comprises: forming, on a semiconductor substrate, a first gate insulating film for memory cell transistors, and a second gate insulating film for a high-voltage transistor of a peripheral circuit; forming on the first gate insulating film a plurality of first gate electrodes for the memory cell transistors, and on the second gate insulating film a second gate electrode for the high-voltage transistor; depositing a first silicon oxide film to fill between the plurality of first gate electrodes and also to extend over a surface of the second gate insulating film positioned on both side portions of the second gate electrode; etching the first silicon oxide film to form a spacer on a side wall portion of the second gate electrode; and forming a silicon nitride film on a surface of the spacer and on the surface of the second gate insulating film positioned on both side portions of the second gate electrode.

In accordance with a third aspect of the present invention, a semiconductor device comprises: a semiconductor substrate; a first gate electrode formed on the semiconductor substrate with a first gate insulating film interposed therebetween; an impurity diffusion region formed in a surface of the semiconductor substrate on both side portions of the first gate electrode; a first silicon oxide film formed on a side wall portion of the first gate electrode and also formed extending over the surface of the semiconductor substrate where the impurity diffusion region is formed; and a first silicon nitride film formed on an upper surface of the first silicon oxide film, a height of the semiconductor substrate at a position where the first gate insulating film is formed being greater than a height of the semiconductor substrate at a position where the first silicon oxide film is formed.

### BRIEF DESCRIPTION OF THE DRAWINGS

FIG. 1 is an equivalent circuit diagram showing a memory cell array in a nonvolatile semiconductor memory device in accordance with a first embodiment.

FIG. 2 is a layout diagram of the memory cell array in the nonvolatile semiconductor memory device in accordance with the first embodiment.

FIG. 3 is a layout diagram of a part of a peripheral circuit region in the nonvolatile semiconductor memory device in accordance with the first embodiment.

FIG. 4 is a layout diagram of a part of the peripheral circuit region in the nonvolatile semiconductor memory device in accordance with the first embodiment.

FIG. 5 is a cross-sectional view of the memory cell array in the nonvolatile semiconductor memory device in accordance with the first embodiment.

FIG. 6 is a cross-sectional view of a part of the peripheral circuit region in the nonvolatile semiconductor memory device in accordance with the first embodiment.

FIG. 7 is a cross-sectional view of a part of the peripheral circuit region in the nonvolatile semiconductor memory device in accordance with the first embodiment.

FIG. 8A is a cross-sectional view showing a method of manufacturing the nonvolatile semiconductor memory device in accordance with the first embodiment.

FIG. 8B is a cross-sectional view showing the method of manufacturing the nonvolatile semiconductor memory device in accordance with the first embodiment.

FIG. 8C is a cross-sectional view showing the method of manufacturing the nonvolatile semiconductor memory device in accordance with the first embodiment.

FIG. 9A is a cross-sectional view showing the method of manufacturing the nonvolatile semiconductor memory device in accordance with the first embodiment.

FIG. 9B is a cross-sectional view showing the method of manufacturing the nonvolatile semiconductor memory device in accordance with the first embodiment.

FIG. 9C is a cross-sectional view showing the method of manufacturing the nonvolatile semiconductor memory device in accordance with the first embodiment.

FIG. 10A is a cross-sectional view showing the method of manufacturing the nonvolatile semiconductor memory device in accordance with the first embodiment.

FIG. 10B is a cross-sectional view showing the method of manufacturing the nonvolatile semiconductor memory device in accordance with the first embodiment.

FIG. 10C is a cross-sectional view showing the method of manufacturing the nonvolatile semiconductor memory device in accordance with the first embodiment.

FIG. 11A is a cross-sectional view showing the method of manufacturing the nonvolatile semiconductor memory device in accordance with the first embodiment.

FIG. 11B is a cross-sectional view showing the method of manufacturing the nonvolatile semiconductor memory device in accordance with the first embodiment.

FIG. 11C is a cross-sectional view showing the method of manufacturing the nonvolatile semiconductor memory device in accordance with the first embodiment.

FIG. 12A is a cross-sectional view showing the method of manufacturing the nonvolatile semiconductor memory device in accordance with the first embodiment.

FIG. 12B is a cross-sectional view showing the method of manufacturing the nonvolatile semiconductor memory device in accordance with the first embodiment.

FIG. 12C is a cross-sectional view showing the method of manufacturing the nonvolatile semiconductor memory device in accordance with the first embodiment.

FIG. 13 is a cross-sectional view of a part of a peripheral circuit region in a nonvolatile semiconductor memory device in accordance with a second embodiment.

FIG. 14 is a cross-sectional view of a part of a peripheral circuit region in a nonvolatile semiconductor memory device in accordance with a variant example of the second embodiment.

FIG. 15A is a cross-sectional view showing a method of manufacturing the nonvolatile semiconductor memory device in accordance with the variant example of the second embodiment.

FIG. 15B is a cross-sectional view showing the method of manufacturing the nonvolatile semiconductor memory device in accordance with the variant example of the second embodiment.

FIG. 15C is a cross-sectional view showing the method of manufacturing the nonvolatile semiconductor memory device in accordance with the variant example of the second embodiment.

FIG. 16A is a cross-sectional view showing the method of manufacturing the nonvolatile semiconductor memory device in accordance with the variant example of the second embodiment.

FIG. 16B is a cross-sectional view showing the method of manufacturing the nonvolatile semiconductor memory device in accordance with the variant example of the second embodiment.

FIG. 16C is a cross-sectional view showing the method of manufacturing the nonvolatile semiconductor memory device in accordance with the variant example of the second embodiment.

FIG. 17A is a cross-sectional view showing the method of manufacturing the nonvolatile semiconductor memory device in accordance with the variant example of the second embodiment.

FIG. 17B is a cross-sectional view showing the method of manufacturing the nonvolatile semiconductor memory device in accordance with the variant example of the second embodiment.

FIG. 17C is a cross-sectional view showing the method of manufacturing the nonvolatile semiconductor memory device in accordance with the variant example of the second embodiment.

### DETAILED DESCRIPTION OF THE EMBODIMENTS

Next, embodiments of the present invention are described in detail with reference to the drawings. In the embodiments, a method of manufacturing a semiconductor device is described using a method of manufacturing a nonvolatile semiconductor memory device, that is, a NAND flash memory, as an example, but the embodiments are not limited to this example. Note that in notation of the drawings in the hereafter-described embodiments, identical symbols are assigned to places having identical configurations, and descriptions thereof are omitted. Moreover, the drawings are in frame format, and the relationship between thickness of each film and planar dimensions, ratios of thicknesses of each of layers, and so on, differ from those in the actual semiconductor device.

### First Embodiment

### Configuration of a Nonvolatile Semiconductor Memory Device in Accordance with a First Embodiment

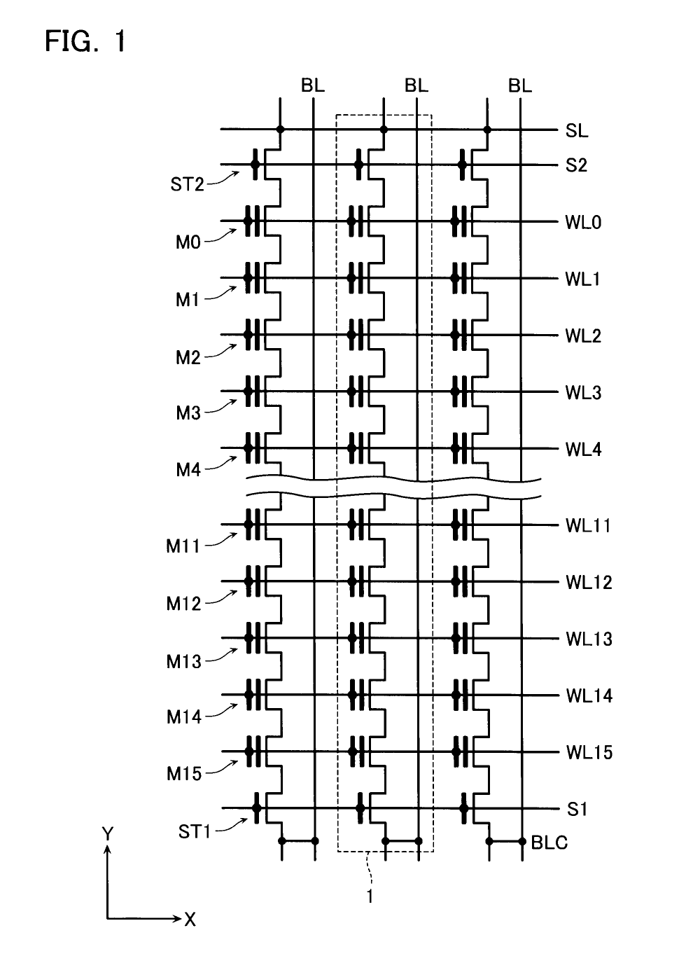

A configuration of a nonvolatile semiconductor memory device in accordance with a first embodiment of the present invention is now described with reference to FIGS. 1-7. First, a configuration of a NAND flash memory in the present embodiment is described.

FIG. 1 is an equivalent circuit diagram showing a part of a memory cell array formed in a memory cell region of a NAND flash memory. A NAND cell unit 1 in the NAND flash memory is configured from two select gate transistors ST1 and ST2, and a plurality of memory cell transistors Mn (where n is an integer from 0 to 15, likewise hereafter) connected in series between the select gate transistors ST1 and ST2. The plurality of memory cell transistors Mn in the NAND cell unit 1 are formed such that adjacent ones share source/drain regions. The memory cell array is configured having NAND cell units 1 provided in line-column form.

The memory cell transistors Mn arranged in an X direction (corresponding to a data select line direction or a gate width direction) of FIG. 1 have their control gate electrodes commonly connected to a data select line (word lines) WLn, respectively. In addition, gate electrodes of the select gate transistors ST1 and ST2 arranged in the X direction of FIG. 1 are commonly connected to select gate lines S1 and S2, respectively. Connected to the drain regions of the select gate transistors ST1 are bit line contacts BLC. This bit line contacts BLC are respectively connected to data transfer lines (bit lines) extending in a Y direction (corresponding to a data transfer line direction or a gate length direction) orthogonal to the X direction of FIG. 1. In addition, the select gate transistors ST2 are connected via its source region to a source line SL extending in the X direction of FIG. 1.

The memory cell transistor Mn is assumed to include n-type source/drain regions formed in a p-type well on a silicon substrate, and to be of a stacked gate structure having a floating gate electrode acting as a charge storage layer and a control gate electrode. In the NAND flash memory, the amount of charge retained in this floating gate electrode is changed in a write operation and an erase operation, thereby changing a threshold voltage of the memory cell MC to store one bit or multiple bits of data. In the NAND flash memory, an assembly of a plurality of NAND cell units 1 sharing word lines configures a block. Erase of data in the NAND flash memory is executed in units of this block.

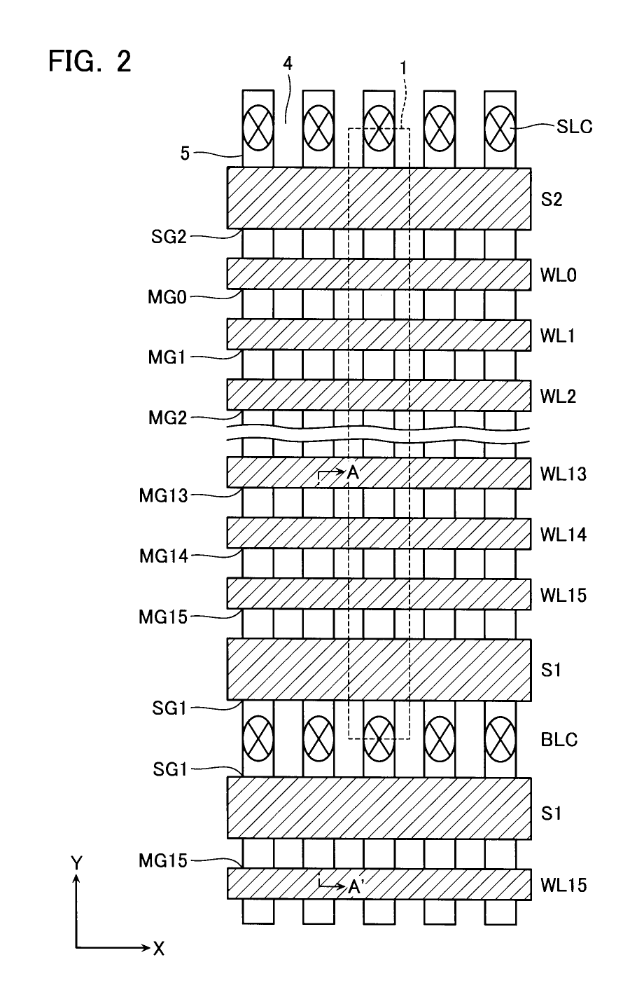

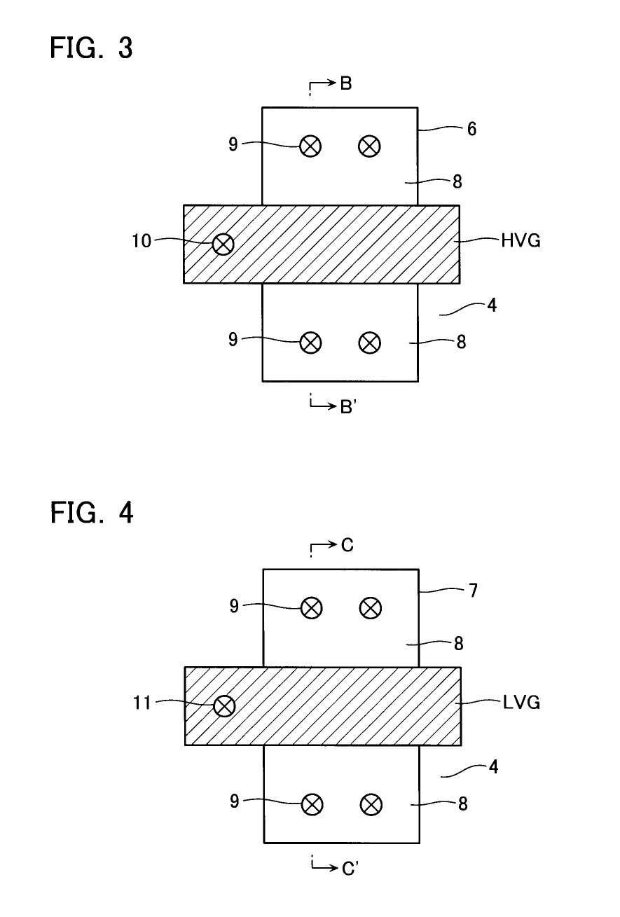

FIG. 2 is a layout diagram of a part of the memory cell array formed in the memory cell region of the NAND flash memory. FIGS. 3 and 4 are layout diagrams of, respectively, a high-voltage transistor and a low-voltage transistor formed in a peripheral circuit region of the NAND flash memory.

As shown in FIG. 2, a plurality of element separating regions 4 each of an STI (Shallow Trench Isolation) structure are formed in a silicon substrate 3 that acts as a semiconductor substrate with a certain spacing along a Y direction of FIG. 2. As a result, there are formed element regions 5 that are separated in an X direction of FIG. 2. The word lines WLn of the memory cell transistors Mn are formed with a certain spacing and along the X direction of FIG. 2 orthogonal to the element regions 5. The word lines WLn form gate electrodes MGn of the memory cell transistors Mn at positions where the element regions 5 intersect the word lines WLn. In addition, the select gate line S1 of the select gate transistors ST1 is formed along the X direction of FIG. 2. The select gate line S1 forms gate electrodes SG1 of the select gate transistors ST1 at positions where the element regions 5 intersect the select gate line S1. Formed respectively in the element region 5 between adjacent select gate lines S1 are the bit line contacts BLC. These bit line contacts BLC are connected to respective bit lines BL not shown that extend in the Y direction of FIG. 2. Moreover, the select gate line S2 of the select gate transistors ST2 is formed along the X direction of FIG. 2. The select gate line S2 forms gate electrodes SG2 of the select gate transistors ST2 at positions where the element regions 5 intersect the select gate line S2. Formed respectively in the element regions 5 between adjacent select gate lines S2 are the source line contacts SLC. These source line contacts SLC are connected to the source line SL not shown that extends in the X direction of FIG. 2.

As shown in FIGS. 3 and 4, a high-voltage transistor HVTr and a low-voltage transistor LVTr formed in the peripheral circuit region are respectively provided in element regions 6 and 7 left remaining in rectangular form in the silicon substrate 3. The element separating regions 4 are formed so as to surround these element regions 6 and 7. Gate electrodes HVG and LVG are respectively formed in each of the element regions 6 and 7 so as to traverse the element regions 6 and 7, and source/drain regions 8 formed by diffusion of impurities are provided on both sides of these gate electrodes HVG and LVG. Contact plugs 9, 10, and 11 are formed in the source/drain regions 8 and the gate electrodes HVG and LVG, respectively.

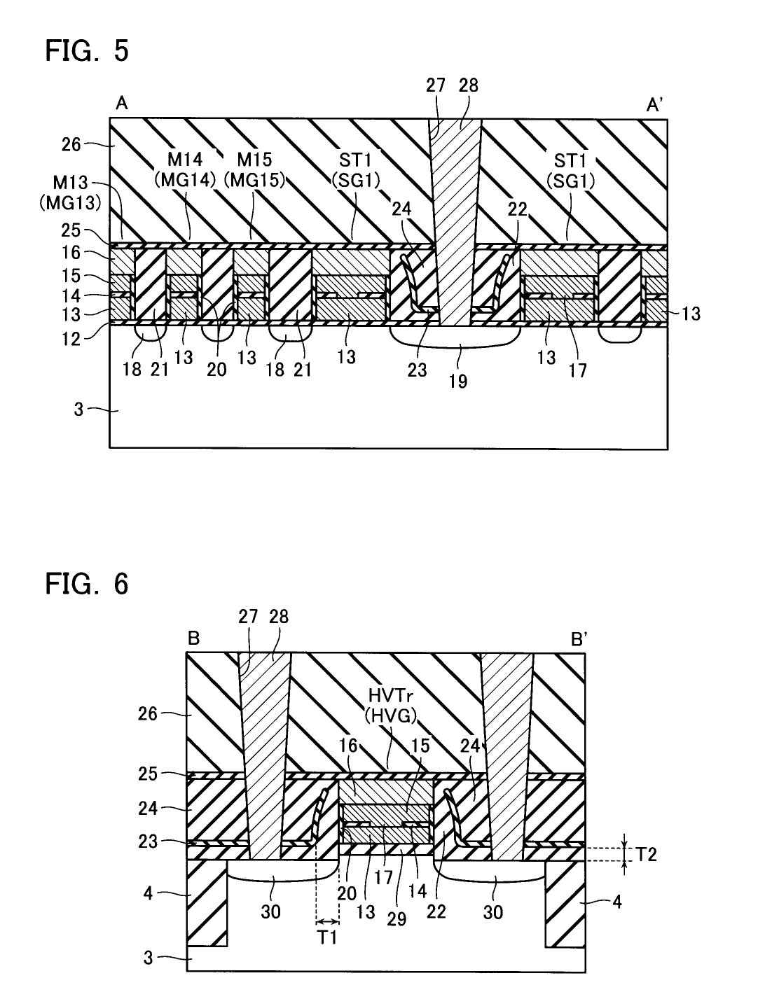

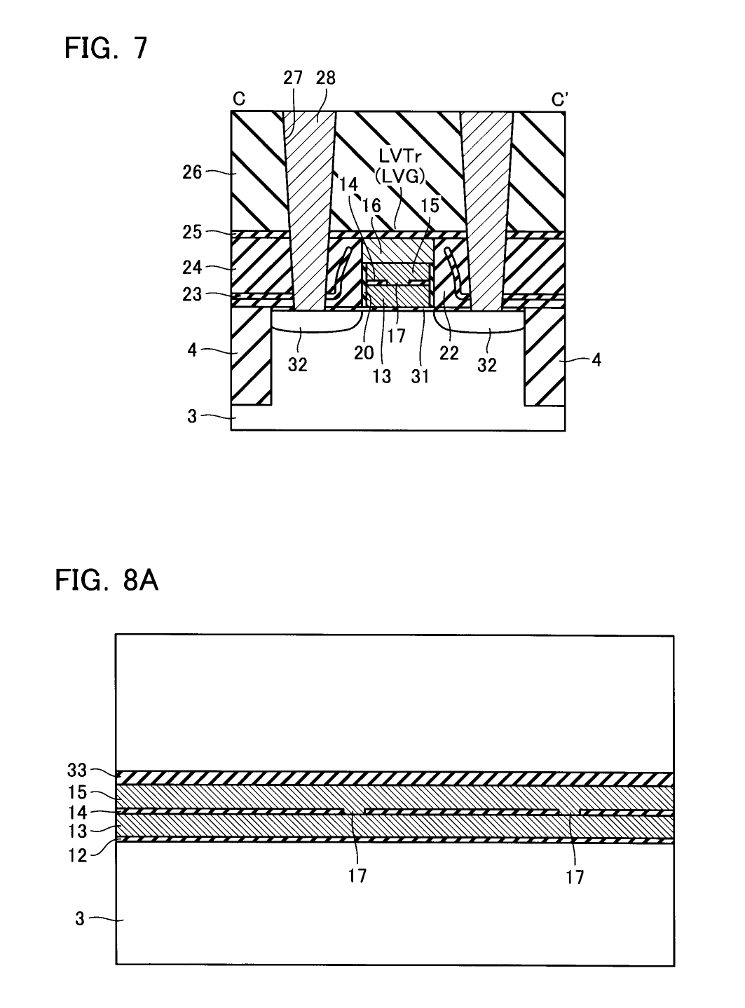

FIGS. 5-7 are cross-sectional views taken along the lines A-A′, B-B′, and C-C′ shown respectively in FIGS. 2-4. FIG. 5 is a cross-sectional view of a part of the memory cell array centered on the gate electrode SG1 portion of the select gate transistor ST1 in the NAND flash memory. FIGS. 6 and 7 are cross-sectional views of the high-voltage transistor HVTr and the low-voltage transistor LVTr formed in the peripheral circuit region of the NAND flash memory.

As shown in FIG. 5, a tunnel insulating film 12 of film thickness 4 nm-16 nm which acts as a gate insulating film is formed on the silicon substrate 3. The gate electrodes MGn (where n is an integer from 0 to 15, likewise hereafter) of the memory cell transistors Mn (where n is an integer from 0 to 15, likewise hereafter) and the gate electrode SG1 of the select gate transistor ST1 are formed on this tunnel insulating layer 12. These gate electrodes MGn and SG1 have a configuration in which a polysilicon film 13 for use as a floating gate electrode, an inter-electrode insulating film 14, a polysilicon film 15 for use as a control gate electrode, and a metal silicide film 16 are stacked sequentially. The inter-electrode insulating film 14 utilizes an ONO structure comprising silicon oxide film-silicon nitride film-silicon oxide film, an NONON structure where the ONO structure is further sandwiched by silicon nitride films, or the like. Furthermore, a high-dielectric constant material or high-permittivity material, for example, aluminum oxide (Al₂O₃), hafnium silicate (HfSiO), or the like, may be included to increase a coupling ratio of the memory cell transistors Mn. The metal silicide film 16 uses a metal silicide film in which tungsten (W), titanium (Ti), cobalt (Co), nickel (Ni), molybdenum (Mo), and so on, are combined with silicon (Si).

Formed in the inter-electrode insulating film 14 of the gate electrode SG1 of the select gate transistor ST1 is an opening 17 to allow conduction between the polysilicon film 13 and the polysilicon film 15. This opening 17 is filled by the polysilicon film 15. Formed in a surface layer (surface) of the silicon substrate 3 between the gate electrodes MGm-MGm+1 (where m is an integer from 0 to 14, likewise hereafter) and between the gate electrodes MG15-SG1 are impurity diffusion regions 18 that become the source/drain regions. The impurity diffusion regions 18 are formed such that adjacent memory cell transistors Mn share source/drain regions. Formed in the surface layer of the silicon substrate 3 between the gate electrodes SG1-SG1 is a high-concentration impurity diffusion region 19. Note that the source/drain region between the gate electrodes SG1-SG1 may also have an LDD (Lightly Doped Drain) structure that includes not only the high-concentration impurity diffusion region 19, but also a shallow low-concentration impurity diffusion region.

A silicon oxide film 20 is formed on a side wall of the gate electrodes MGn and the gate electrode SG1, using, for example, RTP (Rapid Thermal Processing). A silicon oxide film 21 which acts as a first insulating film is formed between the silicon oxide film 20 of the gate electrode MG15 and the gate electrode SG1 and between the silicon oxide film 20 of the gate electrodes MGMm and MGm+1, using, for example, LP-CVD. Moreover, formed in the side wall on a side where a pair of gate electrodes SG1 oppose each other is a spacer 22 made of a silicon oxide film processed onto a surface of the silicon oxide film 20. These silicon oxide film 21 and spacer 22 are formed directly on the silicon substrate 3 or via the tunnel insulating film 12. The spacer 22 which is a silicon oxide film is formed extending over the surface of the silicon substrate 3 between the pair of gate electrodes SG1-SG1 with a film thickness of 5 nm-30 nm. In other words, the spacer 22 is formed continuously over the surface of the silicon substrate between the pair of gate electrodes SG1-SG1. A silicon nitride film 23 which acts as a first barrier insulating film is formed on a surface of this spacer 22 with a film thickness of 5 nm-30 nm. At this time, the above-mentioned extended spacer 22 forms an under-layer of the silicon nitride film 23, and prevents the silicon nitride film 23 from coming into direct contact with the surface of the silicon substrate 3. In addition, an insulating film 24 which acts as a third insulating film is formed on the silicon nitride film 23 between the gate electrodes SG1-SG1 so as to fill between the gate electrodes SG1-SG1, the insulating film 24 being such as a BPSG (Boron Phosphorus Silicate Glass) film or silicon oxide film.

A silicon nitride film 25 which acts as a second barrier insulating film is formed on an upper surface of the gate electrodes MGn and SG1, on an upper surface of the silicon oxide film 21 between the gate electrodes MGm-MGm+1 and between the gate electrodes MG15-SG1, and on an upper surface of the spacer 22 and the insulating film 24, so as to cover these upper surfaces. The silicon nitride film 25 is formed such that its upper surface is at a position higher than a height of an upper surface of the metal silicide film 16. A TEOS film 26 which acts as a fourth insulating film is formed on the silicon nitride film 25 and planarized.

As shown, a contact hole 27 is formed in a region over which the spacer 22 between the gate electrodes SG1-SG1 extends. The contact hole 27 extends from an upper surface of the TEOS film 26 to the surface of the silicon substrate 3. This contact hole 27 is formed so as to penetrate the TEOS film 26, the silicon nitride film 25, the insulating film 24, the silicon nitride film 23, and the spacer 22, and so as to expose the surface of the silicon substrate 3. A contact plug 28 formed by filling with a conductor is formed on an inside of the contact hole 27, the contact plug 28 being electrically connected to the silicon substrate 3. This contact plug 28 configures the bit line contacts BLC shown in FIG. 2.

As shown in FIG. 6, a gate insulating film 29, which acts as a gate insulating film and has a film thickness of, for example, 20 nm-50 nm that is greater than the film thickness of the tunnel insulating film 12, is formed on the silicon substrate 3. The gate electrode HVG of the high-voltage transistor HVTr is formed via this gate insulating film 29. The gate electrode HVG has a configuration in which the polysilicon film 13, the inter-electrode insulating film 14, the polysilicon film 15, and the metal silicide film 16 are stacked sequentially. The inter-electrode insulating film 14 utilizes an ONO structure comprising silicon oxide film-silicon nitride film-silicon oxide film, an NONON structure where the ONO structure is further sandwiched by silicon nitride films, or the like. Furthermore, a high-dielectric constant material or high-permittivity material, for example, aluminum oxide (Al₂O₃), hafnium silicate (HfSiO), or the like, may be included to increase a coupling ratio of the memory cell transistors Mn. The metal silicide film 16 uses a metal silicide film in which tungsten (W), titanium (Ti), cobalt (Co), nickel (Ni), molybdenum (Mo), and so on, are combined with silicon (Si).

Formed in the inter-electrode insulating film 14 of the gate electrode HVG of the high-voltage transistor HVTr is an opening 17 to allow conduction between the polysilicon film 13 and the polysilicon film 15. This opening 17 is filled by the polysilicon film 15. Formed in a surface layer (surface) of the silicon substrate 3 on both sides of the gate electrode HVG are impurity diffusion regions 30 that become the aforementioned source/drain regions 8. Note that the impurity diffusion regions 30 may have an LDD structure.

A silicon oxide film 20 is formed on a side wall of the gate electrode HVG, using, for example, RTP. A spacer 22 that is a processed silicon oxide film is formed on an outer side of the silicon oxide film 20. The spacer 22 is formed extending also over the impurity diffusion regions 30. In other words, the spacer 22 is formed continuously over the impurity diffusion regions 30 from a side surface of the gate electrode HVG. This spacer 22 is formed directly on the silicon substrate 3 so as to be in contact with the silicon substrate 3, and a height of a lower surface of the spacer 22 is constant. A film thickness T2 of the spacer 22 on the silicon substrate 3 is formed so as to be less than a film thickness T1 of the spacer formed on a side wall portion of the gate electrode HVG, the film thickness T2 being in a range of 5 nm-30 nm. The film thickness T1 of the spacer 22 denotes a film thickness of the thickest portion of the spacer 22 formed on the side wall portion of the gate electrode HVG in a direction parallel to a principal plane of the silicon substrate 3. A silicon nitride film 23 which acts as a first barrier insulating film is formed on a surface of this spacer 22 with a film thickness in a range of 5 nm-30 nm. As previously mentioned, the extended spacer 22 prevents the silicon nitride film 23 from coming into direct contact with the surface of the silicon substrate 3. In addition, an insulating film 24 is formed on the silicon nitride film 23 so as to bury the gate electrode HVG, the insulating film 24 being such as a BPSG film or silicon oxide film.

A silicon nitride film 25 which acts as a second barrier insulating film is formed on an upper surface of the gate electrode HVG and on an upper surface of the spacer 22 and the insulating film 24, so as to cover these upper surfaces. A TEOS film 26 is formed on the silicon nitride film 25 and planarized. As shown, a contact hole 27 is formed in a region over which the spacer 22 on the impurity diffusion regions 30 extends. The contact hole 27 extends from an upper surface of the TEOS film 26 to the surface of the silicon substrate 3. This contact hole 27 is formed so as to penetrate the TEOS film 26, the silicon nitride film 25, the insulating film 24, the silicon nitride film 23, and the spacer 22, and so as to expose the surface of the silicon substrate 3. A contact plug 28 formed by filling with a conductor is formed on an inside of the contact hole 27, the contact plug 28 being electrically connected to the silicon substrate 3. This contact plug 28 configures the contact plugs 9 shown in FIG. 3.

As shown here in FIG. 6, a height of the surface of the silicon substrate 3 differs between a portion where the gate electrode HVG of the high-voltage transistor HVTr is formed and a surface portion of the impurity diffusion regions 30. That is, the height of the surface of the silicon substrate 3 where a lower surface of the spacer 22 makes contact with the silicon substrate 3 is slightly lowered with respect to the height of the surface of the silicon substrate 3 where the gate insulating film 29 of the gate electrode HVG is formed. As shown in the description of manufacturing processes described hereafter, this difference in height occurs in an etching process and is termed a silicon gouging. Consequently, the lower surface of the spacer 22 is formed so as to be positioned lower than the surface of the silicon substrate 3 where the gate insulating film 29 is formed. In other words, an interface between the spacer 22 and the silicon substrate 3 is lower than an interface between the gate insulating film 29 and the silicon substrate 3.

As shown in FIG. 7, a thin gate insulating film 31 that is for use in the low-voltage transistor LVTr and which acts as a gate insulating film and has a film thickness the same or close to that of the tunnel insulating film 12 of the memory cell transistors Mn, is formed on the silicon substrate 3. Formed in a surface layer (surface) of the silicon substrate 3 on both sides of the gate electrode LVG are impurity diffusion regions 32 that become the aforementioned source/drain regions 8. Note that the impurity diffusion regions 32 may have an LDD structure. A spacer 22, which is formed on a side wall of the gate electrode LVG of the low-voltage transistor LVTr with a silicon oxide layer 20 interposed therebetween, is formed extending also over the impurity diffusion regions 32 via the gate insulating film 31. In other words, the spacer 22 is formed continuously over the impurity diffusion regions 32 from a side surface of the gate electrode LVG. In addition, a contact plug 28 configures the contact plugs 9 shown in FIG. 4.

### Method of Manufacturing the Nonvolatile Semiconductor Memory Device in Accordance with the First Embodiment

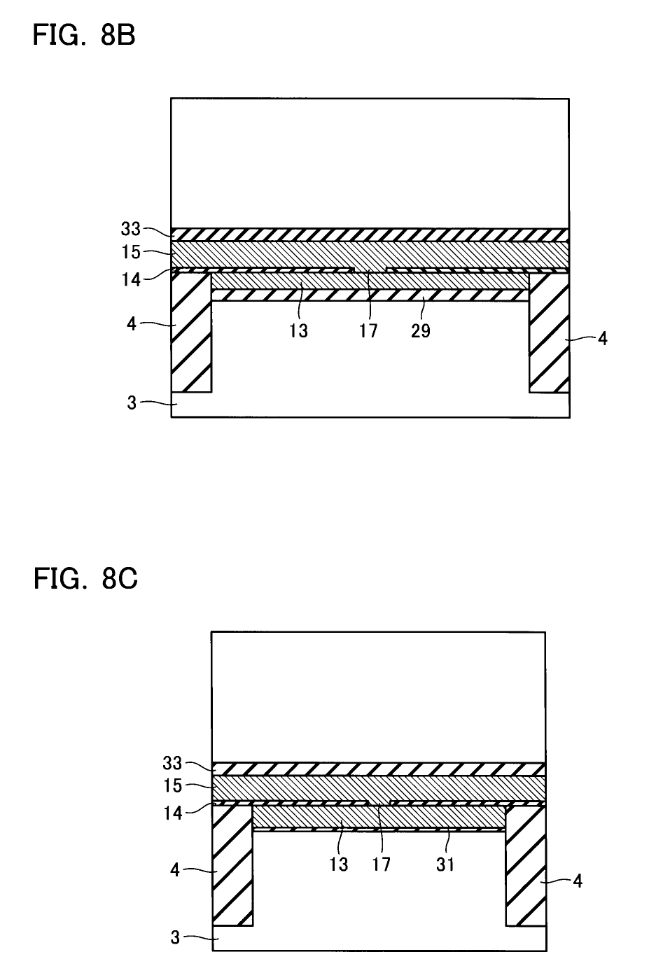

Next, a method of manufacturing the nonvolatile semiconductor memory device in accordance with the present embodiment is described with reference to FIGS. 8A-8C through 12A-12C. FIGS. 8A-12A, FIGS. 8B-12B, and FIGS. 8C-12C are cross-sectional views of manufacturing processes of, respectively, the memory cell array formed in the memory cell region, the high-voltage transistor HVTr formed in the peripheral circuit region, and the low-voltage transistor LVTr formed in the peripheral circuit region.

A stacked structure of the gate electrodes MGn and SG1, HVG, and LVG is formed as shown in FIGS. 8A-8C. Well and channel region is formed in the silicon substrate 3 by ion implantation. The gate insulating film 29 for the high-voltage transistor HVTr is formed on the silicon substrate 3 with a film thickness in a range of 20 nm-50 nm. The gate insulating film 29 is selectively removed only in the memory cell region and a formation region of the low-voltage transistor LVTr. The tunnel insulating film 12 and the gate insulating film 31 for the low-voltage transistor LVTr are formed in the memory cell region and the formation region of the low-voltage transistor LVTr with a film thickness in a range of 4 nm-15 nm. Gate insulating films are thereby formed separately for the formation region of the high-voltage transistor HVTr, and the memory cell region and formation region of the low-voltage transistor LVTr.

The polysilicon film 13 which acts as the floating gate electrode is deposited with a film thickness in a range of 30 nm-200 nm. Widely known lithography and RIE are used, with a silicon nitride film as a mask material, to form a trench which acts as the element separating region, an inside of the trench being filled with a silicon oxide film to form the element separating region 4. The silicon oxide film in the element separating region 4 of the memory cell region is etched back to adjust the coupling ratio of the memory cell transistors Mn, followed by depositing of an ONO film (silicon oxide film-silicon nitride film-silicon oxide film) which acts as the inter-electrode insulating film 14. An NONON film in which silicon nitride layers are further added to both sides of the ONO film, or an insulating film including a high-dielectric constant material or high-permittivity material of the likes of aluminum oxide (Al₂O₃) and hafnium silicate (HfSiO) may be adopted in place of the ONO film.

The polysilicon film 15 which acts as the control gate electrode is deposited with a film thickness of 50 nm-300 nm, followed by depositing of a silicon nitride film 33 which acts as a mask material used during gate electrode processing. Here, the transistors HVTr and LVTr in the peripheral circuit region, and the select gate transistors ST1 and ST2 have each of their polysilicon films 13 and 15 as the floating gate electrode and control gate electrode brought into electrical contact. The opening 17 is thus formed in advance in the inter-electrode insulating film 14 before deposition of the polysilicon film 15, as shown in FIGS. 8A-8C.

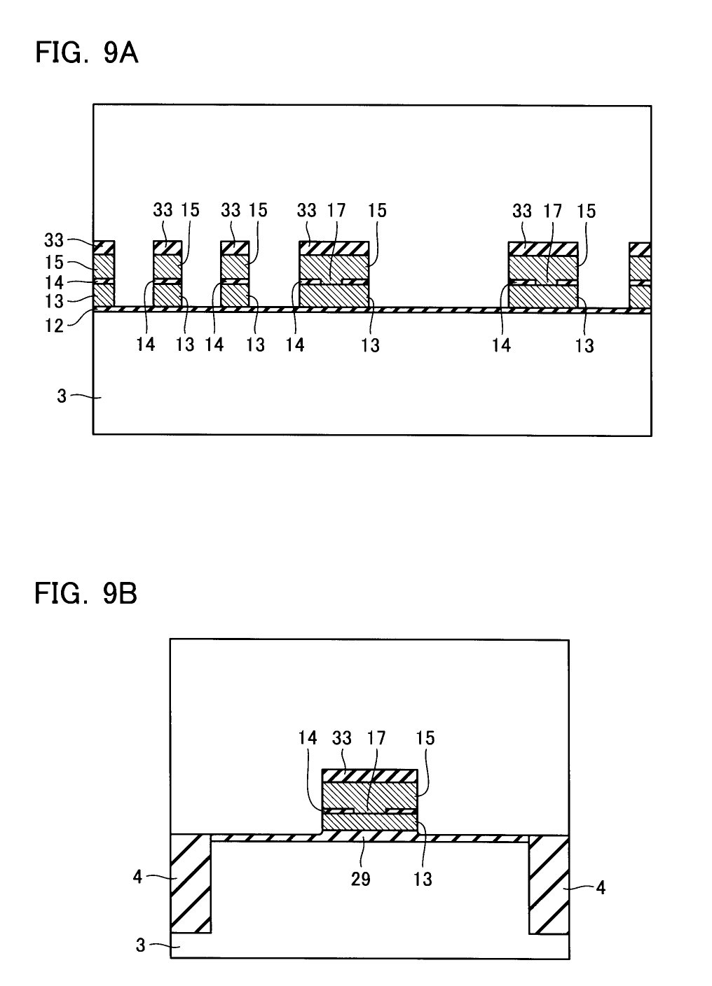

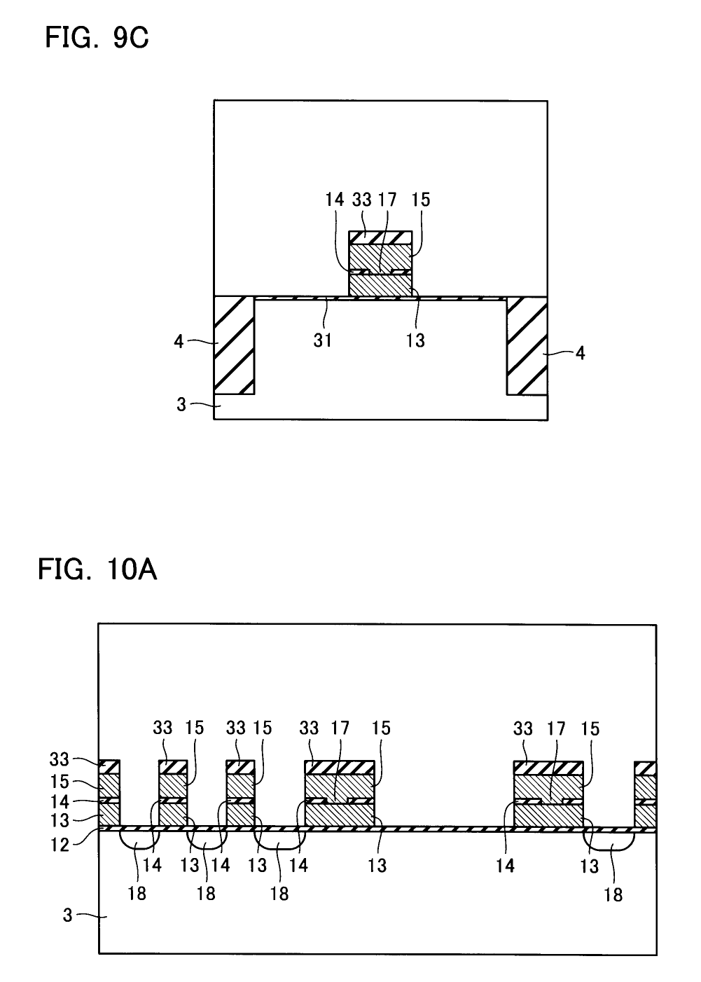

As shown in FIGS. 9A-9C, photolithography and RIE are used to perform patterning of the gate electrodes MGn, SG1, SG2, HVG, and LVG. First, the silicon nitride film 33 and the polysilicon film 15 are etched in sequence. When etching the inter-electrode insulating film 14, an upper surface of the element separating region 4 is lowered by over-etching. That is, the element separating region 4 which projects to an upper surface of the polysilicon film 13 has its upper surface lowered to a vicinity of the tunnel insulating film 12 and gate insulating film 29.

The polysilicon film 13 which becomes the floating gate electrode is selectively etched. If processing of the polysilicon film is performed at this time with the element separating region 4 projecting from the silicon substrate 3, etching residue of the polysilicon film 13 tends to occur in an edge portion of the element separating region 4, which may cause a short circuit. The upper surface of the element separating region 4 is thus lowered in advance. As a result, the plurality of gate electrodes MGn of the memory cell transistors Mn, the gate electrode HVG of the high-voltage transistor HVTr, and the gate electrode LVG of the low-voltage transistor LVTr are respectively formed on the tunnel insulating film 12, the gate insulating film 29, and the gate insulating film 31.

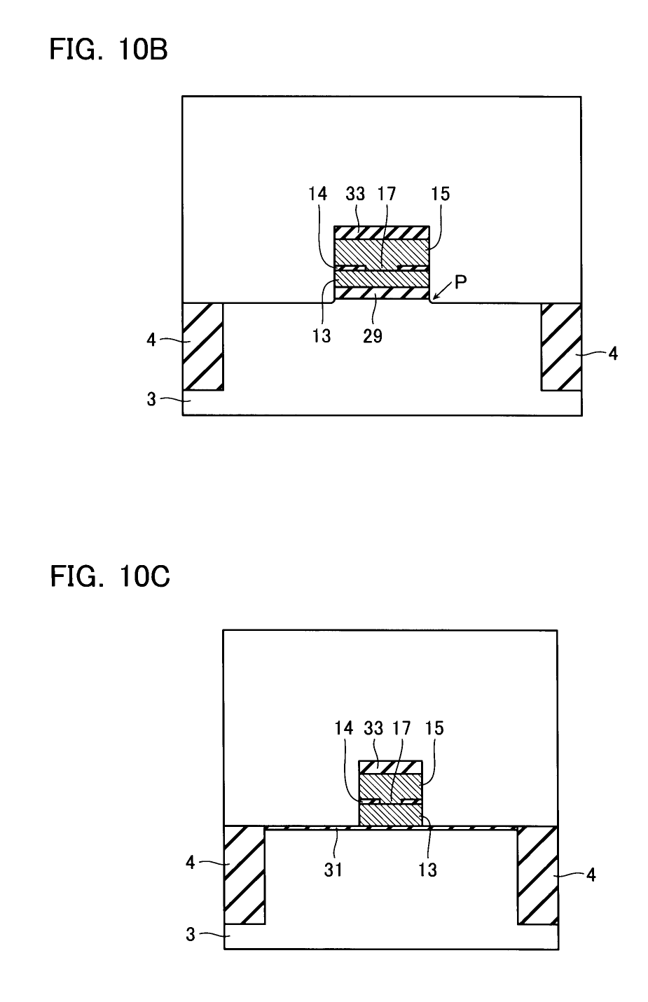

As shown in FIGS. 10A-10C, etching using the gate electrode HVG as a mask is performed to remove the gate insulating film 29 that exists on the silicon substrate 3, namely in a region that subsequently becomes the source/drain region 8, of the gate electrode HVG. Note that process unevenness is taken into account during etching, and this process is performed for an etching time 5%-30% longer than anticipated to be certain of stripping the gate insulating layer 29. Although RIE is performed so as to have a selection ratio with respect to the silicon substrate 3, some gouging of the silicon substrate 3 occurs due to the over-etching. As a result, a silicon gouging P occurs, as shown in FIG. 10B. Ion implantation is used here to form the impurity diffusion regions 18 of the memory cell transistors Mn. Further, the impurity diffusion region 32 of the low-voltage transistor LVTr may be formed by ion implantation using the gate electrode LVG of the low-voltage transistor LVTr as a mask.

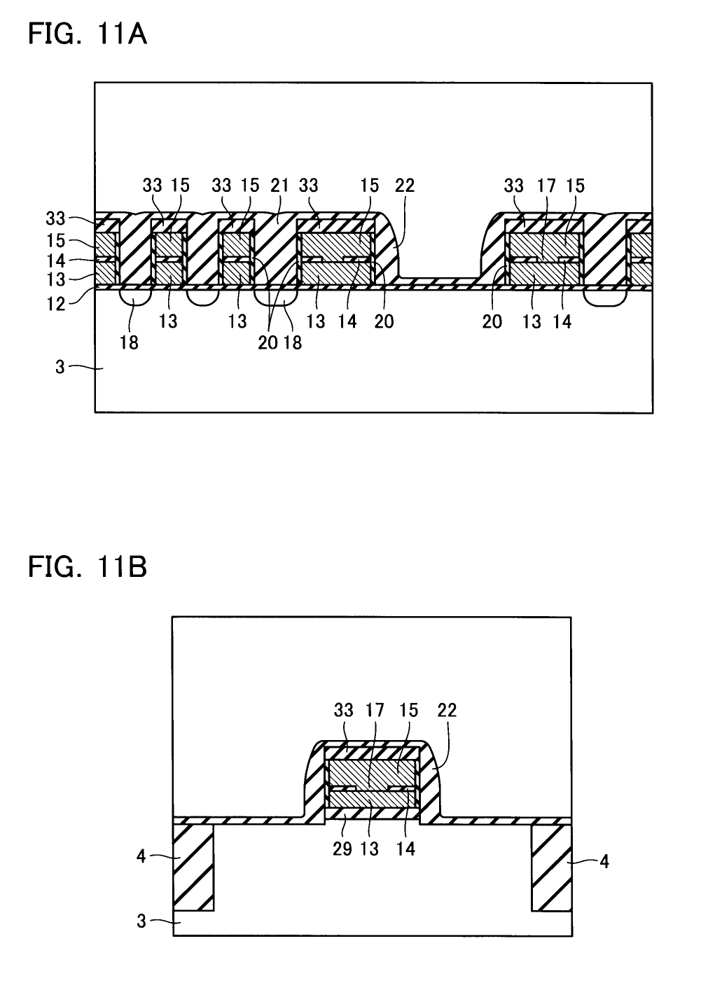

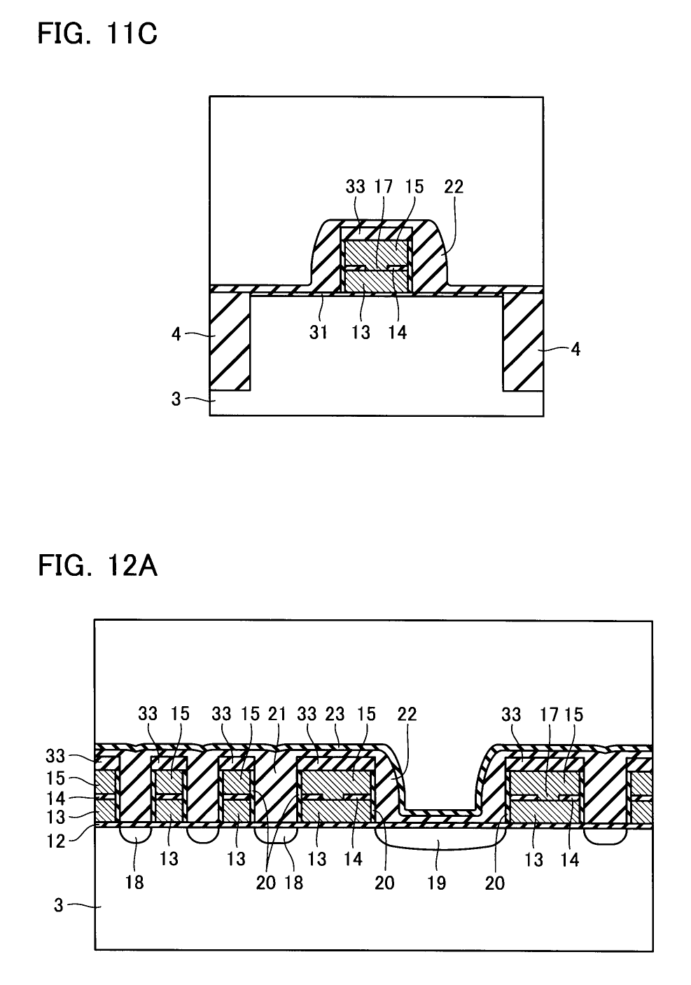

As shown in FIGS. 11A-11C, RTP or the like is used to form the silicon oxide film 20 on side walls of the gate electrodes MGn, SG1, SG2, HVG, and LVG. The silicon oxide film 21 is formed with a film thickness of 10 nm-100 nm in order to fill between each of the gate electrodes MGm-MGm+1 and for formation of the spacer on the side wall of the gate electrodes SG1 and SG2 and on the side wall of gate electrodes HVG and LVG of each of the transistors in the peripheral circuit region. The film thickness of this silicon oxide film 21 is assumed to allow filling between each of the gate electrodes MGm-MGm+1 but not to fill between the gate electrodes SG1-SG1, between gate electrodes HVG and between gate electrodes LVG.

The silicon oxide film 21 is etched, thereby forming the spacer 22 on the side wall of the gate electrodes SG1, SG2, HVG, and LVG, and the silicon oxide film 21 between the gate electrodes MGm-MGm+1. Note that the spacer 22 is formed to extend also over the silicon substrate 3 of the high-voltage transistor HVTr and the low-voltage transistor LVTr. This shape can be obtained by setting an etching time less than a processing time required to completely remove the spacer 22 over the silicon substrate 3. In this case, since etching stops halfway in the spacer 22 and the spacer 22 is not stripped to the silicon substrate 3, the silicon gouging does not occur in this process. Further, the spacer 22 is formed on the side wall of the gate electrode HVG at this time so that its film thickness is greater than the film thickness of the spacer 22 on the silicon substrate 3 (T1>T2, refer to FIG. 6).

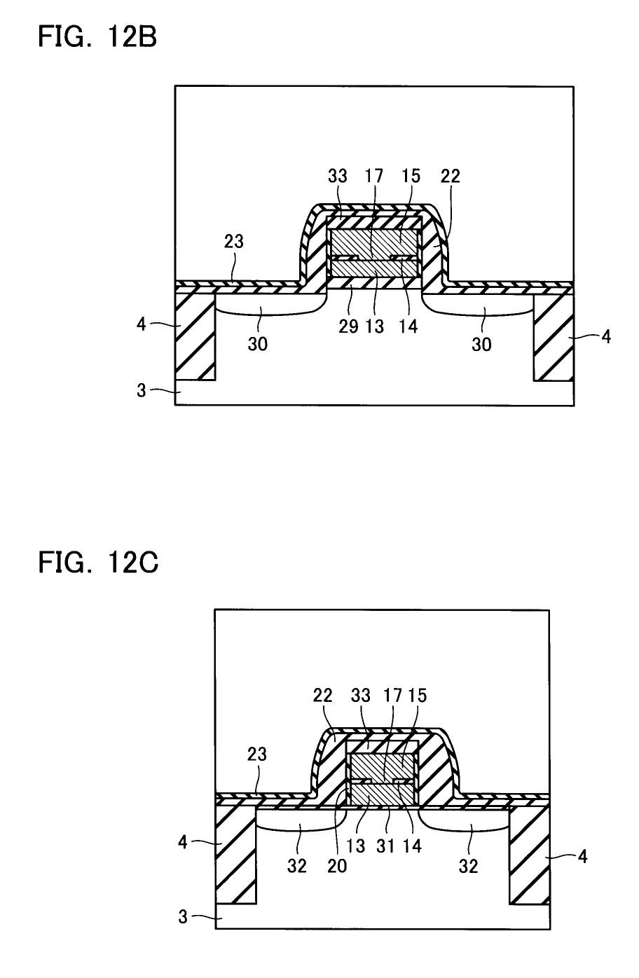

As shown in FIGS. 12A-12C, the impurity diffusion region of each of the transistors is formed. In the case of an NMOS transistor, either or both of, for example, arsenic (As) and phosphorus (P) is/are ion implanted, and in the case of a PMOS transistor, either or both of, for example, boron (B) and boron fluoride (BF₂) is/are implanted, thereby forming the impurity diffusion regions 19, 30, and 32. Since the spacer 22 is present on the silicon substrate 3 at this time, the acceleration energy of ion implantation is adjusted such that ions pass through the spacer 22 to be distributed in the vicinity of an uppermost surface of the silicon substrate 3.

The silicon nitride film 23 is deposited with a film thickness of 5 nm-30 nm. This silicon nitride film 23 is provided to prevent diffusion of impurity from the BPSG film used to fill between the gate electrodes in the following process or from the insulating film 24 that is a silicon oxide film. The silicon nitride film 23 is provided to prevent diffusion of oxidant during an added heating process. In addition, the spacer 22 is provided to prevent the silicon nitride film 23 from coming into direct contact with the silicon substrate 3. Thereby, reliability of the high-voltage transistor HVTr in particular can be improved.

Hereafter, manufacture proceeds by widely known manufacturing processes of a nonvolatile semiconductor memory device. That is, subsequent to filling between the gate electrodes SG1-SG1 and a periphery of the gate electrodes HVG and LVG with the insulating film 24, planarization is performed using CMP (Chemical Mechanical Polishing). The silicon nitride film 33 on the gate electrodes MGn, SG1, SG2, HVG, and LVG is removed, and the metal silicide film 16 is formed. Further, the silicon nitride film 25 is deposited, which silicon nitride film acts as a barrier insulating film to prevent contamination from the metal silicide film 16. Subsequently, the TEOS film 26 is deposited, the contact hole 27 is formed, and filling of the contact plug 28 is performed, thereby forming the NAND flash memory in the present embodiment as shown in FIGS. 5-7.

Hereafter there continue multi-layer wiring processes of upper layers not shown.

### Advantages of the Nonvolatile Semiconductor Memory Device in Accordance with the First Embodiment

The high-voltage transistor HVTr in the NAND flash memory in accordance with the present embodiment has only one silicon gouging and differs in this point from the semiconductor device disclosed in JP 2006-324503 which has two silicon gougings.

The silicon gouging occurs through over-etching due to RIE when removing the gate electrode film 29 of the high-voltage transistor HVTr. Due to the fact that plasma is used to perform etching in RIE, when the silicon substrate 3 is etched by RIE, the etched surface of the silicon substrate 3 receives damage by the plasma. The damage of the surface of the impurity diffusion regions 30 causes the electrical characteristics of the high-voltage transistor HVTr to be affected, leading to deterioration in reliability. Moreover, since the impurity diffusion regions 30 are formed so as to have a peak of impurity concentration in a vicinity of the surface of the silicon substrate 3, if over-etching occurs in RIE, a high concentration portion of the impurity diffusion regions 30 gets etched. This results in the problem that a profile of the impurity diffusion regions 30 differs from what is expected, whereby the electrical characteristics of the high-voltage transistor HVTr are affected.

In the method of manufacturing in the present embodiment, the silicon gouging does not occur in the process for forming the spacer 22. Utilizing the method of manufacturing a semiconductor device in the present embodiment allows the negative-effect-inducing silicon gouging to be reduced from two places to one place. Reducing the number of silicon gougings allows the fundamental electrical characteristics and reliability of the high-voltage transistor HVTr to be improved.

Moreover, when the silicon nitride film 23 of the high-voltage transistor HVTr is deposited directly on the surface of the impurity diffusion regions 30 of the silicon substrate 3, it is envisaged that, when a high electrical field stress is applied to the drain side, hot carriers arising in the vicinity of the drain will be trapped in the silicon nitride film 23. If electrons are trapped in the silicon nitride film 23 on the impurity diffusion regions 30, a fixed charge is generated in the silicon nitride film 23, whereby current flow in the impurity diffusion regions 30 is rendered more difficult. As a result, the on-current of the high-voltage transistor HVTr appears to be reduced, leading to a deterioration in transistor characteristics.

Further, when the silicon nitride film 23 of the high-voltage transistor HVTr is deposited directly on the surface of the impurity diffusion regions 30 of the silicon substrate 3, there is a possibility of stress being applied to the silicon substrate 3, leading to generation of crystal defects in the silicon substrate 3. As a result, a leak current of the high-voltage transistor HVTr increases. Moreover, a high voltage of 20 V-30 V is sometimes applied to the high-voltage transistor HVTr and, if crystal defects are present in such a case, the increase in the leak current is large. The nonvolatile semiconductor memory device of the present embodiment enables the leak current to be reduced effectively.

In the nonvolatile semiconductor memory device of the present embodiment, the spacer 22 is formed as an under-layer of the silicon nitride film 23, whereby the silicon nitride film 23 does not make direct contact with the silicon substrate 3. Improvement in the characteristics of the high-voltage transistor HVTr in particular can thus be attained.

In addition, the nonvolatile semiconductor memory device of the present embodiment is configured such that the silicon nitride film 23 which acts as the first barrier insulating film does not penetrate between the gate electrodes MGn or between the gate electrode MG15 and the gate electrode SG1. The memory cell array can thus be configured without incurring an increase in coupling capacitance between the memory cell transistors Mn. This silicon nitride film 23 acts as a barrier film against diffusion of material such as ions and moisture in the insulating film 24 and TEOS film 26, and against reaction of material in the insulating film 24 and TEOS film 26 with the metal silicide film 16. Additionally, the silicon nitride films 23 and 25 act also as a stopper when forming the contact hole 27. These silicon nitride films 23 and 25 allow improving reliability of the nonvolatile semiconductor memory device.

### Second Embodiment

### Configuration of a Nonvolatile Semiconductor Memory Device in Accordance with a Second Embodiment

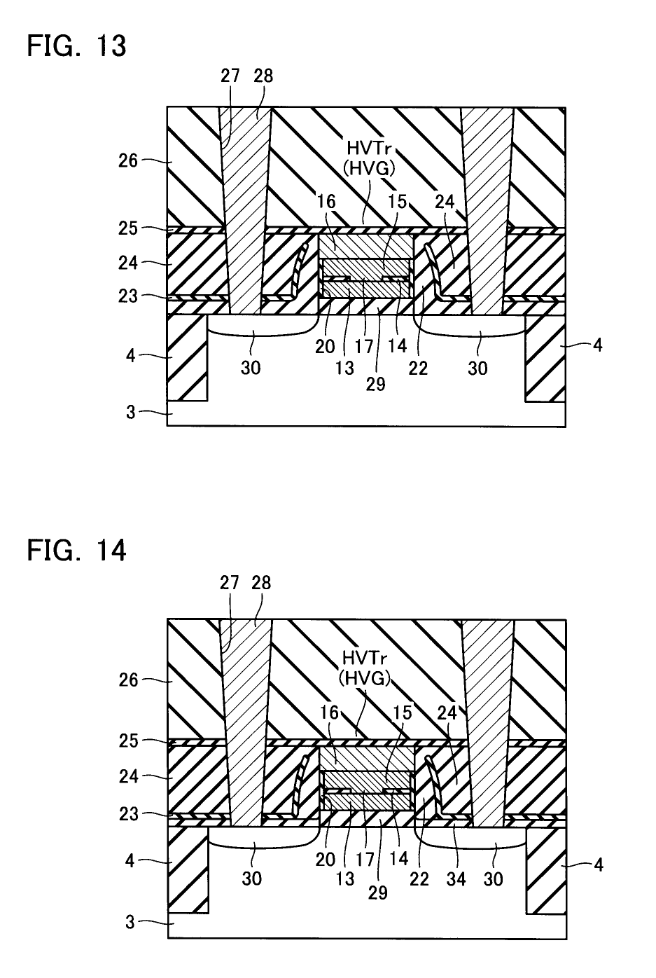

Next, a configuration of a nonvolatile semiconductor memory device in accordance with a second embodiment of the present invention is described with reference to FIG. 13.

FIG. 13 is a cross-sectional view of a high-voltage transistor HVTr formed in a peripheral circuit region of a NAND flash memory. Here, the high-voltage transistor HVTr of the present embodiment is configured to have zero silicon gougings. That is, a height of the silicon substrate 3 where the gate insulating film 29 of the high-voltage transistor HVTr is formed is equal to a height of the silicon substrate 3 where a lower surface of the spacer 22 formed on a side wall of the gate electrode HVG and extending over the impurity diffusion regions 30 makes contact. In other words, a height of interfaces between the gate insulating film 29 and the silicon substrate 3 is equal to that between the spacer 22 and the silicon substrate 3. No difference in height occurs in the silicon substrate 3 of the high-voltage transistor HVTr in the present embodiment. Furthermore, the silicon substrate 3 is substantially flat over the entire surface of the element region partitioned by the element separating regions 4, excluding a place where the contact hole 27 makes contact with the silicon substrate 3.

### Advantages of the Nonvolatile Semiconductor Memory Device in Accordance with the Second Embodiment

In the semiconductor device of the present embodiment, the above-mentioned negative-effect-inducing silicon gouging does not occur. Reducing the number of silicon gougings allows the electrical characteristics and reliability of the high-voltage transistor HVTr to be further improved.

### Variant Example of the Second Embodiment

### Configuration of a Variant Example of the Nonvolatile Semiconductor Memory Device in Accordance with the Second Embodiment

Next, a configuration of a nonvolatile semiconductor memory device in accordance with a variant example of the second embodiment of the present invention is described with reference to FIG. 14.

FIG. 14 is a cross-sectional view of a high-voltage transistor HVTr formed in a peripheral circuit region of a NAND flash memory. Here, the high-voltage transistor HVTr of the present example differs from the second embodiment in that the spacer 22 formed on the side wall of the gate electrode HVG and a silicon oxide film 34 on the impurity diffusion regions 30 differ in composition.

Likewise in the NAND flash memory of the present example, the height of the silicon substrate 3 where the gate insulating film 29 of the high-voltage transistor HVTr is formed is equal to the height of the silicon substrate 3 where a lower surface of the silicon oxide film 34 extending over the impurity diffusion regions 30 makes contact. In other words, heights of interfaces between the gate insulating film 29 and the silicon substrate 3 and between the silicon oxide film 34 and the silicon substrate 3 are equal. Furthermore, the silicon substrate 3 is substantially flat over the entire surface of the element region partitioned by the element separating regions 4, excluding a place where the contact hole 27 makes contact with the silicon substrate 3.

The spacer 22 that is a processed silicon oxide film is formed on a side wall of the gate electrode HVG of the high-voltage transistor HVTr in the present example. In addition, the silicon oxide film 34 having a composition that differs from that of the spacer 22 is formed on the impurity diffusion regions 30. This silicon oxide film 34 is formed directly on the silicon substrate 3 so as to be in contact with the silicon substrate 3, and a height of the lower surface of the silicon oxide film 34 is constant. A film thickness of the silicon oxide film 34 on the silicon substrate 3 is in a range of 5 nm-30 nm. The silicon nitride film 23 which acts as the first barrier insulating film is formed on surfaces of these spacer 22 and silicon oxide film 34 with a film thickness in a range of 5 nm-30 nm. The silicon oxide film 34 prevents the silicon nitride film 23 from making direct contact with the surface of the silicon substrate 3.

The silicon oxide film 34 on the impurity diffusion regions 30 makes direct contact with the silicon substrate 3 over a large area, and can be thus formed by a silicon oxide film of high reliability, for example, a thermally-oxidized film. In contrast, it is possible to use a material of high step-coverage for the silicon oxide film when forming the spacer 22 in consideration of the application of the spacer 22. The silicon oxide film used in the spacer 22 rarely make contact with the silicon substrate 3, and a silicon oxide film such as a TEOS film, for example, may thus be adopted therefor. As described above, it is possible to use a material having a different composition to that of the thermally-oxidized film for the spacer 22.

Note that the difference in these silicon oxide film materials can be confirmed from the difference in etching rates in wet etching using for example a chemical solution. Generally, the etching rate for a TEOS film is higher than that for a thermally-oxidized film. As a result, if etching with for example a hydrofluoric acid solution is performed subsequent to removal of the silicon nitride film 23 on the spacer 22 and silicon oxide film 34, only the spacer 22 that is the TEOS film is removed, and a part of the silicon oxide film 34 that is the thermally-oxidized film is left unremoved. Such confirmation allows the difference in composition of the silicon oxide films to be determined.

### Method of Manufacturing the Nonvolatile Semiconductor Memory Device in Accordance with the Second Embodiment and the Variant Example of the Second Embodiment

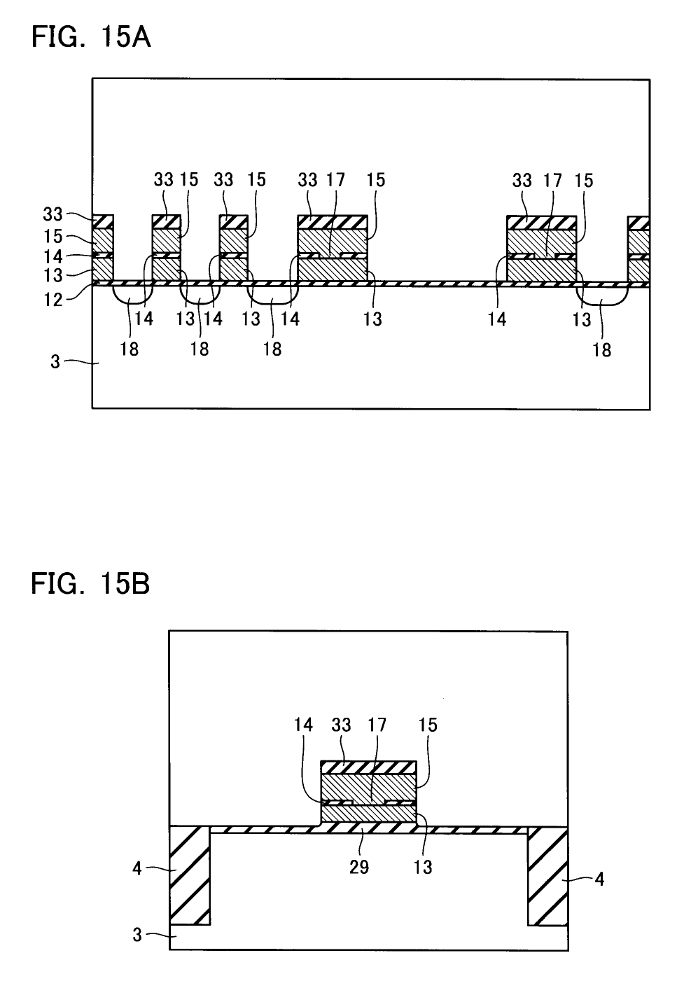

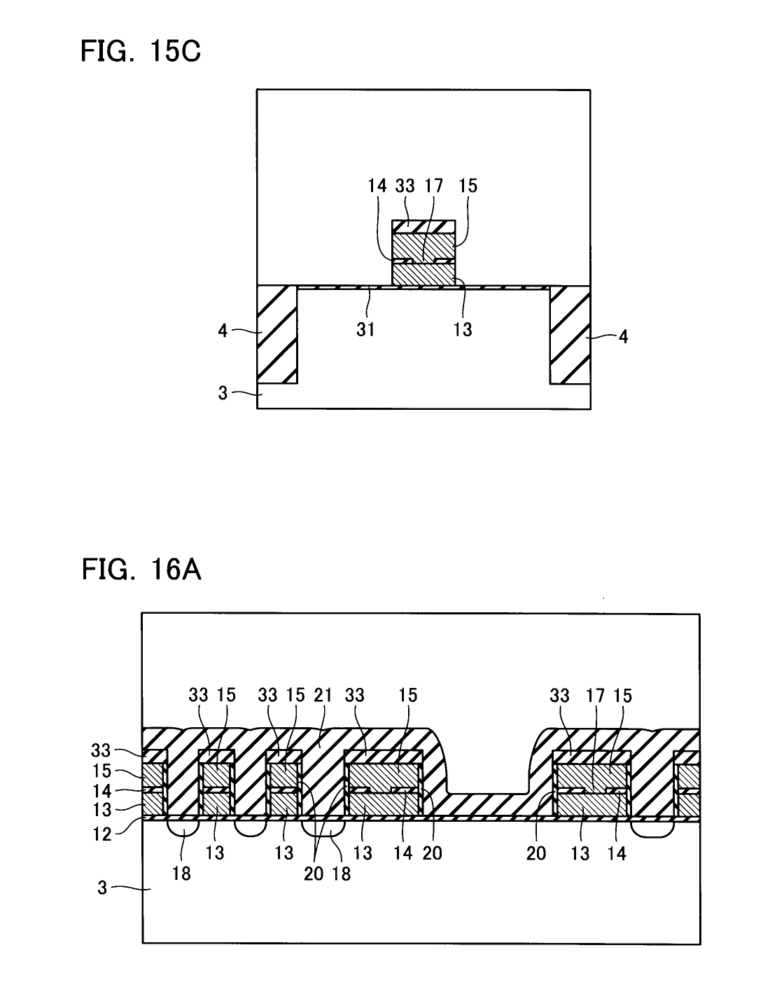

Next, a method of manufacturing the nonvolatile semiconductor memory device in accordance with the second embodiment and the variant example of the second embodiment is described with reference to FIGS. 15A-15C through 17A-17C. FIGS. 15A-17A, FIGS. 15B-17B, and FIGS. 15C-17C are cross-sectional views of manufacturing processes of, respectively, the memory cell array formed in the memory cell region, the high-voltage transistor HVTr formed in the peripheral circuit region, and the low-voltage transistor LVTr formed in the peripheral circuit region.

A stacked structure of the gate electrodes MGn, SG1, SG2, HVG, and LVG is formed as shown in FIGS. 15A-15C. The method of manufacturing in accordance with the second embodiment is similar to the method of manufacturing in the first embodiment as far as the processes shown in FIGS. 9A-9C. However, in the method of manufacturing in accordance with the variant example of the second embodiment, the gate insulating film 29 for the high-voltage transistor HVTr, the tunnel insulating film 12 in the memory cell region, and the gate insulating film 31 for the low-voltage transistor LVTr are formed by thermal oxidation.

As shown in FIGS. 15A-15C, in the method of manufacturing the nonvolatile semiconductor memory device in accordance with the second embodiment and the variant example of the second embodiment, in the process thereof that corresponds to FIG. 10, an upper portion of the gate insulating film 29 is removed by etching using the gate electrode HVG as a mask and the gate insulating film 29 exists on the silicon substrate 3, namely in a region that subsequently becomes the source/drain region 8, of the high-voltage transistor HVTr. At this time, a part of an upper portion of the gate insulating film 29 extending over the silicon substrate 3 is removed. That is, the gate insulating film 29 extending over the silicon substrate 3 is not completely removed, and a part of a lower portion of the gate insulating film 29 is left remaining. As a result, a film thickness of the gate insulating film 29 existing below the gate electrode HVG becomes greater than the film thickness of the gate insulating film 29 existing in places other than below the gate electrode HVG (refer to FIG. 15B). Ion implantation is used here to form the impurity diffusion regions 18 of the memory cell transistors Mn. Further, the impurity diffusion region 32 of the low-voltage transistor LVTr may be formed by ion implantation using the gate electrode LVG of the low-voltage transistor LVTr as a mask.

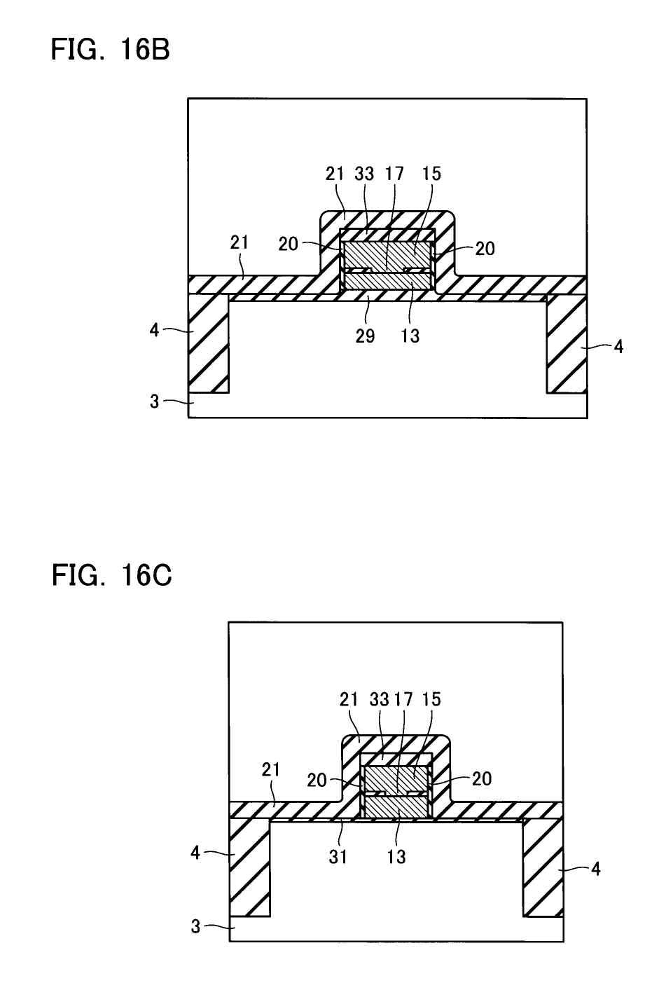

As shown in FIGS. 16A-16C, RTP or the like is used to form the silicon oxide film 20 on side walls of the gate electrodes MGn, SG1, SG2, HVG, and LVG. The silicon oxide film 21 is formed with a film thickness of 10 nm-100 nm in order to fill between each of the gate electrodes MGm-MGm+1 and for formation of the spacer on the side wall of the gate electrodes SG1 and SG2 and on the side wall of gate electrodes HVG and LVG of each of the transistors in the peripheral circuit region. In the method of manufacturing in accordance with the second embodiment, a film of the same composition as that of the gate insulating film 29 of the high-voltage transistor HVTr is utilized for the silicon oxide film 21. In contrast, in the method of manufacturing in accordance with the variant example of the second embodiment, a TEOS film having high step-coverage is utilized for the silicon oxide film 21.

The film thickness of this silicon oxide film 21 is assumed to allow filling between each of the gate electrodes MGm-MGm+1 but not to fill between the gate electrodes SG1-SG1, between gate electrodes HVG and between gate electrodes LVG. Note that between the gate electrodes SG1-SG1 and SG2-SG2 of the select gate transistors ST1 and ST2, and on the silicon substrate 3 of the low-voltage transistor LVTr, the TEOS film 21 is deposited via the tunnel insulating film 12 or directly on the silicon substrate 3.

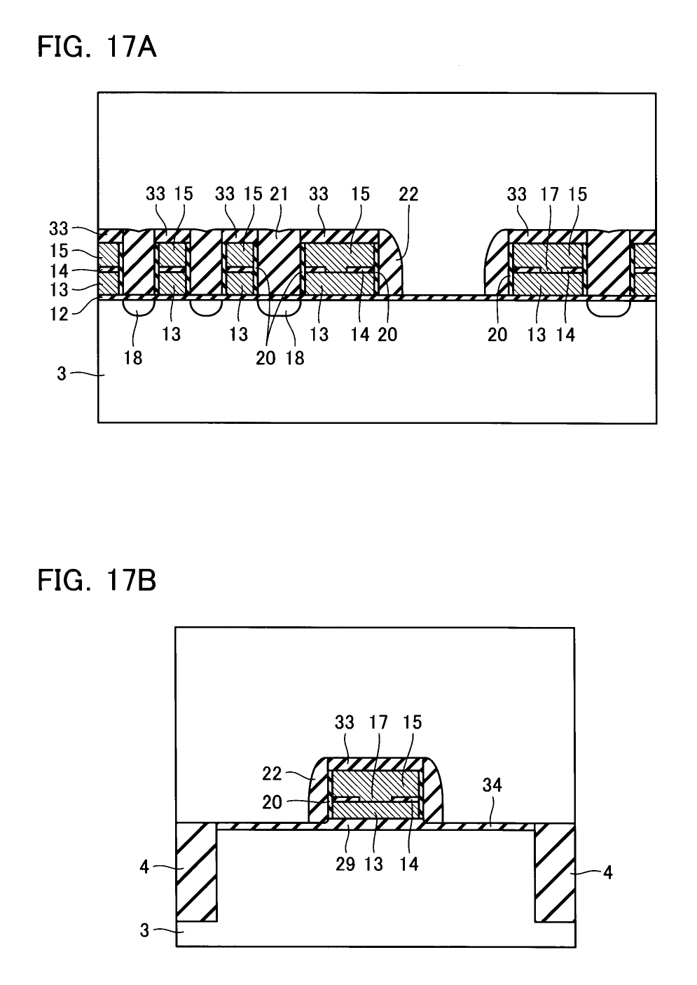

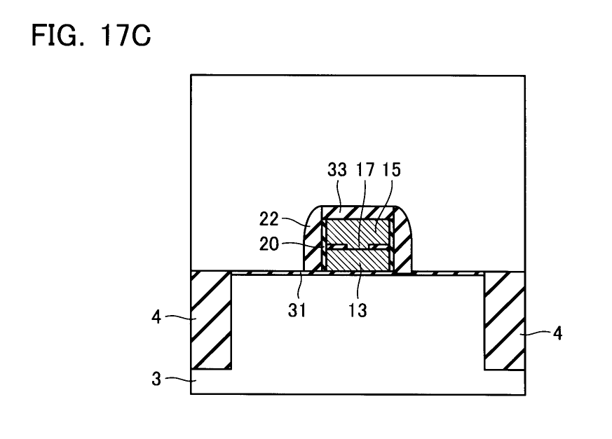

As shown in FIGS. 17A-17C, the silicon oxide film 21 is etched back to form the spacer 22 on the side walls of the gate electrodes SG1, SG2, HVG, and LVG. Here, the silicon oxide film 34 on the source/drain regions 8 of the high-voltage transistor HVTr is the part of the lower portion of the gate insulating film 29 that was left unremoved in the foregoing process.

During etching back in the present process, etching is performed for a time allowing complete removal of the TEOS film 21 deposited on the silicon substrate 3 between the gate electrodes SG1-SG1 and SG2-SG2 of the select gate transistors ST1 and ST2, and on the silicon substrate 3 of the low-voltage transistor LVTr, respectively. The silicon substrate 3 or tunnel insulating film 12 between the gate electrodes SG1-SG1 and SG2-SG2, and the silicon substrate 3 or tunnel insulating film 12 of the low-voltage transistor LVTr are thereby respectively exposed. In contrast, the silicon oxide film 34 (part of the gate insulating film 29) on the silicon substrate 3 of the high-voltage transistor HVTr is left remaining. This enables states shown in FIGS. 17A-17C to be obtained. In this case, the silicon oxide film 34 acts as a protective film during etching back of the silicon oxide film 21 and prevents stripping as far as the silicon substrate 3, with the result that silicon gouging does not occur in the present process.

Now in the method of manufacturing in accordance with the second embodiment, films of the same composition are utilized for the spacer 22 and the silicon oxide film 34. Thus, as shown in FIG. 13, the spacer 22 formed on the side wall of the gate electrode HVG and the spacer 22 extending over the impurity diffusion regions 30 cannot be distinguished. As a result, the spacer 22 formed on the side wall of the gate electrode HVG is recognized to extend over the impurity diffusion regions 30.

However, in the method of manufacturing in accordance with the variant example of the second embodiment, the silicon oxide film 34 is the gate insulating film 29 formed by the thermally-oxidized film, while the silicon oxide film forming the spacer 22 is the TEOS film having high step-coverage. That is, the compositions of the spacer 22 and the silicon oxide film 34 are different.

Ions are implanted to form the impurity diffusion regions 19, 30, and 32 of each of the transistors. This process may be executed at any of times of a state prior to depositing the silicon oxide film 21 shown in FIGS. 15A-15C, a state subsequent to depositing the silicon oxide film 21 shown in FIGS. 16A-16C, and a state subsequent to forming the spacer 22 shown in FIGS. 17A-17C. Ion species and dose amount in this ion implantation are similar to those of the first embodiment, but the acceleration energy of the ion implantation must be adjusted in accordance with the thickness of the silicon oxide film on the silicon substrate 3 at the time the ion implantation is performed.

Hereafter, and similarly to the first embodiment, the silicon nitride film 23 is deposited with a film thickness of 5 nm-30 nm, and then widely known manufacturing processes of a nonvolatile semiconductor memory device are used to form the NAND flash memory in the present embodiment as shown in FIGS. 13 and 14. The silicon nitride film 23 is provided to prevent diffusion of impurity from the BPSG film used to fill between the gate electrodes or from the insulating film 24 that is a silicon oxide film, and to prevent diffusion of oxidant during an added heating process.

### Advantages of the Nonvolatile Semiconductor Memory Device in Accordance with the Second Embodiment and the Variant Example of the Second Embodiment

The NAND flash memory in accordance with the present embodiment has no occurrence of a silicon gouging in the high-voltage transistor HVTr.

In the method of manufacturing a semiconductor device in accordance with the present embodiment, there is no exposure of the silicon substrate 3 in the region where the high-voltage transistor HVTr is formed, from the time that the gate insulating film 29 is formed in an initial stage of the manufacturing processes. Silicon gougings can therefore be restrained to zero. In other words, using the method of manufacturing a semiconductor device in the present embodiment allows the NAND flash memory to be formed without generating a silicon gouging. Reducing the number of times of silicon gougings enables the electrical characteristics and reliability of the high-voltage transistor HVTr to be improved over those of the first embodiment.

Moreover, in the nonvolatile semiconductor memory device of the present embodiment, the silicon oxide film 34 is formed as an under-layer of the silicon nitride film 23, whereby there is no direct contact of the silicon nitride film 23 with the silicon substrate 3. This enables an improvement in characteristics of the high-voltage transistor HVTr in particular to be attained.

In addition, the method of manufacturing in accordance with the variant example of the present embodiment allows the spacer 22 of the high-voltage transistor HVTr to be formed as a TEOS film, and the silicon oxide film 34 on the impurity diffusion regions 30 of the high-voltage transistor HVTr to be formed as a thermally-oxidized film. Since each of the silicon oxide films can be set to have a different composition, the reliability of the silicon oxide film 34 can be improved and the step-coverage of the spacer 22 can also be improved.

This concludes description of embodiments of the present invention, but it should be noted that the present invention is not limited to the above-described embodiments, and that various alterations, additions, combinations, and so on, are possible within a range not departing from the scope and spirit of the invention. For example, the number of memory cell transistors Mn connected in series between the select gate transistors ST1 and ST2 need only be a plurality, and is not limited to 16.

What is claimed is:

1. A method of manufacturing a semiconductor device, comprising:
forming, on a semiconductor substrate, a first gate insulating film for memory cell transistors, and a second gate insulating film for a high-voltage transistor of a peripheral circuit;
forming on the first gate insulating film a plurality of first gate electrodes for the memory cell transistors, and on the second gate insulating film a second gate electrode for the high-voltage transistor;
removing the second gate insulating film positioned on the semiconductor substrate on both side portions of the second gate electrode;
forming an impurity diffusion region in a surface of the semiconductor substrate positioned on both side portions of the first gate electrodes and the second gate electrode;
depositing a first silicon oxide film to fill between the plurality of first gate electrodes and also to extend over surfaces of the second gate electrode and the impurity diffusion region;
etching the first silicon oxide film to form a spacer such that the spacer is formed on a side wall portion of the second gate electrode and also extends over the surface of the semiconductor substrate where the impurity diffusion region is provided; and
forming a silicon nitride film on a surface of the spacer.

2. The method of manufacturing a semiconductor device according to claim 1,
wherein, during forming the first and second gate insulating films, a film thickness of the second gate insulating film is formed greater than a film thickness of the first gate insulating film.

3. The method of manufacturing a semiconductor device according to claim 1,
wherein, during etching the first silicon oxide film, etching is performed so that etching stops halfway in the first silicon oxide film formed extending over the surface of the semiconductor substrate.

4. The method of manufacturing a semiconductor device according to claim 1,
wherein, during removing the second gate insulating film, removing is performed by etching the second gate insulating film until the semiconductor substrate is exposed.

5. A method of manufacturing a semiconductor device, comprising:
forming, on a semiconductor substrate, a first gate insulating film for memory cell transistors, and a second gate insulating film for a high-voltage transistor of a peripheral circuit;
forming on the first gate insulating film a plurality of first gate electrodes for the memory cell transistors, and on the second gate insulating film a second gate electrode for the high-voltage transistor;
depositing a first silicon oxide film to fill between the plurality of first gate electrodes and also to extend over a surface of the second gate insulating film positioned on both side portions of the second gate electrode;
etching the first silicon oxide film to form a spacer on a side wall portion of the second gate electrode; and
forming a silicon nitride film on a surface of the spacer and on the surface of the second gate insulating film positioned on both side portions of the second gate electrode.

6. The method of manufacturing a semiconductor device according to claim 5, further comprising:
removing an upper portion of the second gate insulating film positioned on the semiconductor substrate on the both side portions of the second gate electrode, subsequent to forming the plurality of first gate electrodes and the second gate electrode.

7. The method of manufacturing a semiconductor device according to claim 5,
wherein the second gate insulating film and the first silicon oxide film are formed by films of differing composition.

8. The method of manufacturing a semiconductor device according to claim 5,
wherein the second gate insulating film is formed by a thermally-oxidized film, and the first silicon oxide film is formed by a TEOS film.

9. The method of manufacturing a semiconductor device according to claim 5,
wherein the second gate insulating film and the first silicon oxide film are formed by films of identical composition.

10. The method of manufacturing a semiconductor device according to claim 5,
wherein, during forming the first and second gate insulating films, a film thickness of the second gate insulating film is formed greater than a film thickness of the first gate insulating film.

11. The method of manufacturing a semiconductor device according to claim 6, further comprising:
forming an impurity diffusion region in a surface of the semiconductor substrate positioned on both side portions of the second gate electrode, subsequent to removing an upper portion of the second gate insulating film.

12. A semiconductor device, comprising:
a semiconductor substrate;
a first gate electrode formed on the semiconductor substrate with a first gate insulating film interposed therebetween;
an impurity diffusion region formed in a surface of the semiconductor substrate on both side portions of the first gate electrode;
a first silicon oxide film formed on a side wall portion of the first gate electrode and also formed extending over the surface of the semiconductor substrate where the impurity diffusion region is formed; and
a first silicon nitride film formed on an upper surface of the first silicon oxide film,
a height of the semiconductor substrate at a position where the first gate insulating film is formed being greater than a height of the semiconductor substrate at a position where the first silicon oxide film is formed.

13. The semiconductor device according to claim 12,
wherein the semiconductor substrate at the position where the first silicon oxide film is formed is substantially flat.

14. The semiconductor device according to claim 12,
wherein a film thickness of the first silicon oxide film on the side wall portion of the first gate electrode in a direction parallel to a principal plane of the silicon substrate is formed greater than a film thickness of the first silicon oxide film formed extending over the surface of the semiconductor substrate in a direction vertical to the principal plane of the silicon substrate.

15. The semiconductor device according to claim 12, further comprising:
a second gate electrode formed on the semiconductor substrate with a second gate insulating film interposed therebetween, a film thickness of the second gate insulating film being formed less than a film thickness of the first gate insulating film;
an impurity diffusion region formed in a surface of the semiconductor substrate on both side portions of the second gate electrode;
a second silicon oxide film formed on a side wall portion of the second gate electrode and also formed extending over the surface of the semiconductor substrate where the impurity diffusion region is formed; and
a second silicon nitride film formed on an upper surface of the second silicon oxide film, and
wherein the semiconductor substrate at the position where the second silicon oxide film and the second gate insulating film is formed is substantially flat.

16. The semiconductor device according to claim 15,
wherein the second gate insulating film is extending over the surface of the semiconductor substrate where the impurity diffusion region is formed and interposed between the second silicon oxide film and the semiconductor substrate.
